(19) United States
(12) Patent Application Publication
(10) Pub. No.: US 2005/0168952 A1
(43) Pub. Date: Aug. 4, 2005

(54) Semiconductor package

(75) Inventors: Chin-Te Chen, Taichung Hsien (TW); Han-Ping Pu, Taichung Hsien (TW)

Correspondence Address: EDWARDS & ANGELL, LLP, P.O. BOX 55874, BOSTON, MA, 02205, US

(73) Assignee: Siliconware Precision Industries Co., Ltd., Taichung Hsien (TW)

(21) Appl. No.: 10/974,513

(22) Filed: Oct. 26, 2004

(30) Foreign Application Priority Data
Feb. 4, 2004 (TW) 093102461

(51) Int. Cl. H05K 7/20

(52) U.S. Cl. 361/704

(57) ABSTRACT

A semiconductor package includes a substrate; a chip mounted on a surface of the substrate; a lid having a flat portion and a support portion extending from the flat portion, wherein the support portion is attached to the substrate, with the chip being encompassed by the flat portion, the support portion and the substrate, and at least one cut-away portion is formed at an outer edge of a surface of the support portion attached to the substrate; an adhesive for attaching the lid to the substrate and filling the cut-away portion to allow an applied amount of the adhesive to be observed from the cut-away portion; and a plurality of solder balls mounted on another surface of the substrate. The applied amount of the adhesive can be adjusted optimally by provision of the cut-away portion to improve bonding strength between the lid and substrate and prevent flash of the adhesive.

### FIELD OF THE INVENTION

The present invention relates to semiconductor packages, and more particularly, to a semiconductor package that allows inspection and control of an amount of an adhesive applied between a heat sink and a substrate, so as to increase the bonding strength of the heat sink and the substrate.

### BACKGROUND OF THE INVENTION

Flip-Chip Ball Grid Array (FCBGA) semiconductor package is a package structure combining a flip chip with a ball grid array, in which at least one chip is electrically connected to a surface of a substrate via a plurality of solder bumps, and a plurality of solder balls acting as input/output (I/O) connections are mounted on an opposite surface of the substrate. This type of semiconductor package can advantageously reduce the overall size thereof, and also reduce resistance while enhancing the electrical performance thereof due to no conventional bonding wire being required, thereby preventing signal degradation during transmission. Thus, the FCBGA package becomes the mainstream technology for packaging chips and electronic elements in the next generation.

By the above superior characteristics on the reduced size and enhanced performance, the FCBGA packaging technology is widely used for packaging a plurality of highly integrated chips. However, in such a multi-chip FCBGA package, a relatively larger amount of heat would be produced during operation than other types of semiconductor packages. Therefore, heat dissipation efficiency plays an important role in determining the quality and yield of packaged products. In a typical FCBGA package, a heat sink is attached to a non-active surface of the chip via an adhesive, making heat directly transmitted from the chip through the adhesive and the heat sink to outside of the package, which thus provides relatively better heat dissipation efficiency than other types of semiconductor packages.

Conventionally, in the FCBGA package, as shown in FIG. 1, the heat sink 110 is attached to a substrate 100 via an adhesive or solder 120. The heat sink 110 has a larger surface area than the chip 130 so as to provide better heat dissipation efficiency. However, considering the substrate layout design, the attachment area between the heat sink 110 and the substrate 100 cannot be made large, which thereby causes a limitation on the bonding strength between the heat sink 110 and the substrate 100. Particularly when there are passive components mounted on the substrate 100 for improving the electrical performance, the attachment area between the heat sink 110 and the substrate 100 would be further reduced. In this case, if the amount of the adhesive 120 used is not sufficient, the heat sink 110 may easily delaminate from the substrate 100 during a subsequent shock test or due to other external forces, resulting in an impaired product. On the other hand, if the amount of the adhesive 120 applied is excessive, the adhesive 120 would flash and degrade the quality of the product.

Moreover, the heat sink 110 is shaped as a square lid, which is attached to the substrate 100 and covers and receives the chip 130 therein. As a result, during the attaching process, it is difficult to check the amount and coverage of the adhesive 120 that has been applied on the substrate 100 from the appearance of the heat sink 110. Consequently, the applied amount of the adhesive 120 may be insufficient or excessive, making the heat sink 110 fall from the substrate 100 due to weak bonding strength between the heat sink 110 and the substrate 100, or causing flash of the adhesive 120 used in excess.

A few of solutions to the above problems have been provided. For example, as shown in FIGS. 2A and 2B, one or more square or dovetailed cavities 230 are formed on a surface of the heat sink 210, 210′ in contact with a substrate 200, 200′, so as to increase the contact area between a heat sink 210, 210′ and an adhesive 220, 220′ and thus enhance the bonding strength between the heat sink 210, 210′ and the substrate 200, 200′. This method may solve the problem of insufficient bonding strength between the heat sink and the substrate. However, during the process of applying the adhesive 220, 220′, it is still not able to inspect the amount and coverage of the adhesive 220, 220′ being applied on the substrate 200, 200′. As a result, an undesirable situation may possibly occur that the cavities 230 are not completely filled with the adhesive 220, 220′, making the product yield hard to be improved. Moreover, the dovetailed or square cavities 230 requires difficult processing, thereby increasing the fabrication cost and process complexity.

Another solution is proposed in U.S. Pat. No. 5,825,086. As shown in FIGS. 3A, 3B and 3C, an excessive amount of an adhesive 320, 320′, 320″ is applied on a substrate 300, 300′, 300″ to attach a heat sink 310, 310′, 310″ thereon so as to increase the bonding strength between the heat sink 310, 310′, 310″ and the substrate 300, 300′, 300″. Apart from the enhanced bonding strength, however, the excessive adhesive 320, 320′, 320″ may flash to unintended area on the substrate 300, 300′ 300″, which not only adversely affects the appearance and quality of the product but also leads to a material waste. It is even worse that if the excessive adhesive 320, 320′, 320″ is accidentally spilled to the chip or over an active surface of the chip, it would degrade the electrical performance of the chip and the product yield.

Thus, the conventional technology cannot provide effective solutions to the problems on the attachment between the heat sink and the substrate. That is, if the amount of the adhesive is not enough, the heat sink may fall off from the substrate due to insufficient bonding strength. On the other hand, when the amount of the adhesive is in excess, the adhesive may flash and affect the electrical performance of the chip.

Therefore, it is greatly desired to develop a semiconductor package, which allows an applied amount of the adhesive to be inspected from the appearance of the heat sink and controlled optimally so as to prevent flash and ensure the bonding strength between the heat sink and the substrate as well as reduce the fabrication cost.

### SUMMARY OF THE INVENTION

An objective of the present invention is to provide a semiconductor package, which has a simple structure and allows a used amount of an adhesive to be inspected from the appearance of the package.

Another objective of the invention is to provide a semiconductor package with increased bonding strength between a heat-sink lid and a substrate.

Still another objective of the invention is to provide a semiconductor package, which allows the amount of the adhesive to be adjusted and controlled.

A further objective of the invention is to provide a semiconductor package in which the bonding area between the heat-sink lid and the substrate can be increased.

A further objective of the invention is to provide a semiconductor package for which the product yield is improved.

A further objective of the invention is to provide a semiconductor package, which is cost-effective to fabricate and suitable for mass production.

In order to achieve the foregoing and other objectives, the present invention proposes a semiconductor package comprising: a substrate having a first surface and an opposing second surface; at least one semiconductor chip mounted on the first surface of the substrate and electrically connected to the substrate; a lid having a flat portion and a support portion extending from the periphery of the flat portion, wherein the support portion is attached to the first surface of the substrate, allowing the chip to be received in a space formed by the flat portion, the support portion and the substrate, and wherein at least one cut-away portion is formed at an outer edge of a surface of the support portion attached to the substrate; an adhesive applied between the support portion of the lid and the first surface of the substrate for attaching the support portion to the substrate and filling the cut-away portion of the lid to allow an applied amount of the adhesive to be observed from the cut-away portion; and a plurality of solder balls mounted on the second surface of the substrate.

The cut-away portion on the support portion of the lid can be a rounded corner, a beveled surface or a stepped structure. Particularly, the rounded corner can have different radii or different central angles; the beveled surface may have different slopes; and the stepped structure may have various numbers of steps or different step heights. Further, the cut-away portion can be formed by a combination of the above-mentioned structures, or even formed as an irregularly shaped structure depending on the applied amount of the adhesive.

By provision of the above variously shaped cut-away portions, the amount and coverage of the adhesive being applied between the support portion of the lid and the substrate can be easily inspected and adjusted, so as to prevent flash of the adhesive and achieve satisfactory adhesion between the lid and the substrate in the use of an optimal amount of the adhesive. Moreover, the cut-away portion also increases the bonding area between the support portion and the substrate, thereby further enhancing the bonding strength between the lid and the substrate as well as improving the product yield and facilitating the mass production.

### BRIEF DESCRIPTION OF THE DRAWINGS

The invention can be more fully understood by reading the following detailed description of the preferred embodiments, with reference made to the accompanying drawings, wherein:

FIG. 1 (PRIOR ART) is a schematic diagram of a conventional semiconductor package;

FIGS. 2A and 2B (PRIOR ART) are schematic diagrams of other conventional semiconductor packages;

FIGS. 3A, 3B and 3C (PRIOR ART) are schematic diagrams showing a semiconductor package disclosed by U.S. Pat. No. 5,825,086;

FIG. 4 is a schematic diagram of a semiconductor package in accordance with a preferred embodiment of the present invention; and

FIGS. 5A, 5B and 5C are schematic diagrams of semiconductor packages in accordance with other preferred embodiments of the present invention.

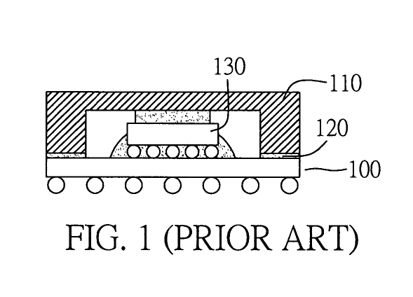

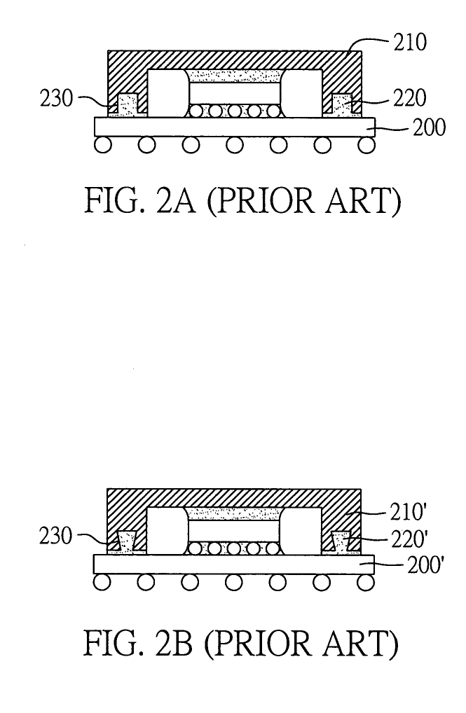

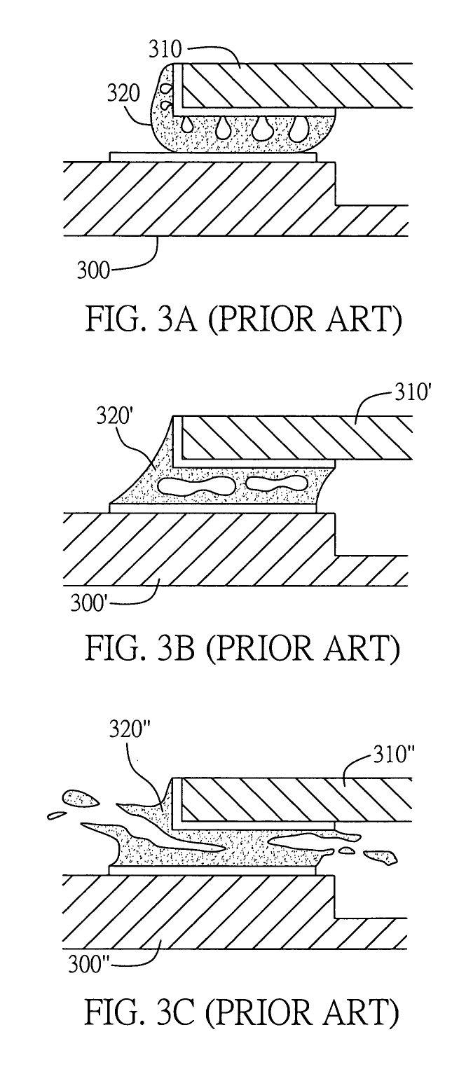

### DETAILED DESCRIPTION OF THE PREFERRED EMBODIMENTS

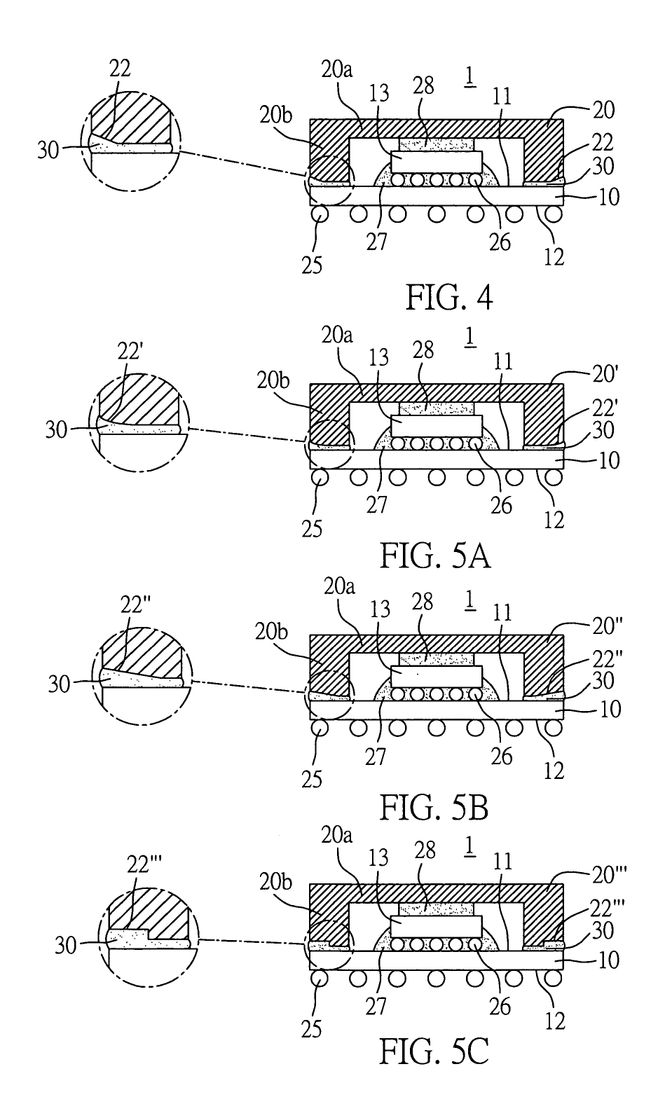

The preferred embodiments of a semiconductor package proposed in the present invention are described in detail below with reference to FIGS. 4 and 5A-5C.

It should be noted that for the sake of simplicity, only the elements or components of the semiconductor package associated with the present invention are shown in the drawings. Shapes, connection manners between elements or components, and the number of elements or components should be more complex and flexible in practice for the semiconductor package.

Referring to FIG. 4, the semiconductor package 1 in the present invention can be a FCBGA package, comprising a substrate 10 having a first surface 11 and an opposing second surface 12; a semiconductor chip 13 mounted on the first surface 11 of the substrate 10; and a lid 20 serving as a heat sink mounted on the first surface 11 of the substrate 10, wherein the lid 20 comprises a flat portion 20a and a support portion 20b extending from the periphery of the flat portion 20a, and the support portion 20b is attached to the first surface 11 of the substrate 10 via an adhesive 30, allowing the chip 13 to be received in a space formed by the flat portion 20a, the support portion 20b and the substrate 10. An outer edge of a surface of the support portion 20b attached to the substrate 10 is formed with at least one upwardly recessed cut-away portion 22, such that the adhesive 30 applied between the support portion 20b to the first surface 11 of the substrate 10 also fills the cut-away portion 22. The semiconductor package 1 further comprises a plurality of solder balls 25 mounted on the second surface 12 of the substrate 10, allowing signals from the chip 13 to be transmitted via the substrate 10 and the solder balls 25 to external devices.

The above chip 13 is electrically connected to the first surface 11 of the substrate 10 in a flip-chip manner via a plurality of conductive bumps 26, and an underfill insulating material 27 is filled around and between the conductive bumps 26 so as to secure the conductive bumps 26 in position. The semiconductor package 1 further comprises a thermally conductive adhesive 28 for attaching the flat portion 20a of the lid 20 to the chip 13, such that heat generated by the chip 13 can be dissipated via the conductive adhesive 28 and the lid 20 to outside of the semiconductor package 1. Besides to dissipate heat, the lid 20 can also be used to prevent external moisture from entering the semiconductor package 1 and damaging the internal elements or components of the semiconductor package 1. This thereby assures proper functioning of the semiconductor package 1 and increases the lifetime of the semiconductor package 1.

A characteristic feature of the present invention is the provision of the cut-away portion 22 on the support portion 20b of the lid 20. With the cut-away portion 22 being provided, when the adhesive 30 is applied on the substrate 10 and the support portion 20b of the lid 20 is attached to the adhesive 30, the applied amount and coverage of the adhesive 30 can be easily observed and inspected from the cut-away portion 22 and then can be adjusted if necessary, so as to prevent flash of the adhesive 30 and to achieve satisfactory adhesion between the lid 20 and the substrate 10 in the use of an optimal amount of the adhesive 30. Moreover, the cut-away portion 22 formed on the support portion 20b of the lid 20 also increases the bonding area between the lid 20 and the substrate 10, making the lid 20 more strongly attached to the substrate 10 and thereby enhancing the bonding strength between the lid 20 and the substrate 10. Further, formation of the cut-away portion 22 employs simple technology and does not increase the fabrication cost. Therefore, the product yield can be desirably improved in a cost-effective way.

As shown in FIGS. 5A, 5B and 5C, the cut-away portions 22′, 22″ and 22′″ of the lids 20′, 20″ and 20′″ can be flexibly shaped as a rounded corner, a beveled surface and a stepped structure respectively. Particularly, the rounded corner can have different radii or different central angles; the beveled surface may have different slopes; and the stepped structure may have various numbers of steps or different step heights. Further, the cut-away portion can be formed by a combination of the above-mentioned structures or even as an irregularly shaped structure, as long as the provision of the cut-away portion allows the amount of the adhesive 30 being applied between the support portion 20b of the lid 20 and the substrate 10 to be observed and checked from the appearance of the semiconductor package 1.

The present invention has been described using exemplary preferred embodiments. However, it is to be understood that the scope of the invention is not limited to the disclosed embodiments. On the contrary, it is intended to cover various modifications and similar arrangements. The scope of the claims, therefore, should be accorded the broadest interpretation so as to encompass all such modifications and similar arrangements.

1. A semiconductor package, comprising:
a substrate having a first surface and an opposing second surface;
at least one semiconductor chip mounted on the first surface of the substrate and electrically connected to the substrate;
a lid having a flat portion and a support portion extending from the periphery of the flat portion, wherein the support portion is attached to the first surface of the substrate, allowing the chip to be received in a space formed by the flat portion, the support portion and the substrate, and wherein at least one cut-away portion is formed at an outer edge of a surface of the support portion attached to the substrate; and
an adhesive applied between the support portion of the lid and the first surface of the substrate for attaching the support portion to the substrate and filling the cut-away portion of the lid to allow an applied amount of the adhesive to be observed from the cut-away portion.

2. The semiconductor package of claim 1, further comprising a plurality of solder balls mounted on the second surface of the substrate.

3. The semiconductor package of claim 1, wherein the lid is a heat sink.

4. The semiconductor package of claim 1, wherein the cut-away portion is a rounded corner.

5. The semiconductor package of claim 1, wherein the cut-away portion is a beveled surface.

6. The semiconductor package of claim 1, wherein the cut-away portion is a stepped structure.

7. The semiconductor package of claim 1, wherein the cut-away portion is a combination of a rounded corner, beveled surface and stepped structure.

8. The semiconductor package of claim 1, wherein the cut-away portion is an irregularly shaped structure.

9. The semiconductor package of claim 1, wherein the chip is electrically connected to the first surface of the substrate via a plurality of conductive bumps.

10. The semiconductor package of claim 9, further comprising an insulating material filled around and between the conductive bumps.

11. The semiconductor package of claim 1, further comprising a thermally conductive adhesive for attaching the flat portion of the lid to the chip.

12. The semiconductor package of claim 1, which is a FCBGA (Flip-Chip Ball Grid Array) semiconductor package.
